(19) United States
(12) Patent Application Publication
(10) Pub. No.: US 2020/0063258 A1
(43) Pub. Date: Feb. 27, 2020

(54) FILM-FORMING METHOD AND FILM-FORMING APPARATUS

(71) Applicant: TOKYO ELECTRON LIMITED, Tokyo (JP)

(72) Inventors: Tsuyoshi TAKAHASHI, Nirasaki City (JP); Noboru MIYAGAWA, Nirasaki City (JP); Susumu ARIMA, Nirasaki City (JP); Seokhyoung HONG, Nirasaki City (JP); Hiroaki ASHIZAWA, Nirasaki City (JP)

(21) Appl. No.: 16/545,588

(22) Filed: Aug. 20, 2019

(30) Foreign Application Priority Data
Aug. 23, 2018 (JP) 2018156684

(51) Int. Cl. C23C 16/455; C23C 16/34

(52) U.S. Cl. CPC C23C 16/45531; C23C 16/345; C23C 16/45544

(57) ABSTRACT

A method of forming a TiSiN film having a desired film characteristic includes: forming a TiN film by executing an operation of supplying, into a process container in which a substrate is accommodated, a Ti-containing gas and a nitrogen-containing gas in this order a number of times X, X being an integer of 1 or more; and forming a SiN film by executing an operation of supplying, into the process container, a Si-containing gas and a nitrogen-containing gas in this order a number of times Y, Y being an integer of 1 or more, wherein forming a TiN film and forming a SiN film are executed in this order a number of times Z, Z being an integer of 1 or more, and wherein, in forming a SiN film, a flow rate of the Si-containing gas is controlled to be a flow rate determined according to the desired film characteristic.

### CROSS-REFERENCE TO RELATED APPLICATION

This application is based upon and claims the benefit of priority from Japanese Patent Application No. 2018-156684, filed on Aug. 23, 2018, the entire contents of which are incorporated herein by reference.

### TECHNICAL FIELD

The present disclosure relates to a film-forming method and a film-forming apparatus.

### BACKGROUND

There is known a method of forming a TiSiN film on a substrate using a titanium-containing gas, a silicon-containing gas, and a nitrogen-containing gas (see, for example, Patent Documents 1 to 4).

### RELATED ART DOCUMENT

### Patent Documents

[Patent Document 1] Japanese Patent Laid-Open Publication No. 2003-226972

[Patent Document 2] Japanese Patent Laid-Open Publication No. 2005-11940

[Patent Document 3] Japanese Patent Laid-Open Publication No. 2013-145796

[Patent Document 4] Japanese Patent Laid-Open Publication No. 2015-514161

### SUMMARY

According to an embodiment of the present disclosure, there is provided a method of forming a TiSiN film having a desired film characteristic, the method including: forming a TiN film by executing an operation of supplying, into a process container in which a substrate is accommodated, a Ti-containing gas and a nitrogen-containing gas in this order a number of times X, X being an integer of 1 or more; and forming a SiN film by executing an operation of supplying, into the process container, a Si-containing gas and a nitrogen-containing gas in this order a number of times Y, Y being an integer of 1 or more, wherein forming a TiN film and forming a SiN film are executed in this order a number of times Z, Z being an integer of 1 or more, and wherein, in forming a SiN film, a flow rate of the Si-containing gas is controlled to be a flow rate determined according to the desired film characteristic.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a film-forming method of a TiSiN film according to an embodiment.

FIG. 2 is a schematic view illustrating an exemplary configuration of a film-forming apparatus.

FIG. 3 is a diagram representing an exemplary relationship between a DCS flow rate and resistivity.

FIG. 4 is a diagram representing an exemplary relationship between a Si concentration in a film and resistivity.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limiting embodiments of the present disclosure will be described with reference to the accompanying drawings. In all the accompanying drawings, the same or corresponding members or components will be denoted by the same or corresponding reference numerals, and redundant explanations will be omitted.

(Film-Forming Method)

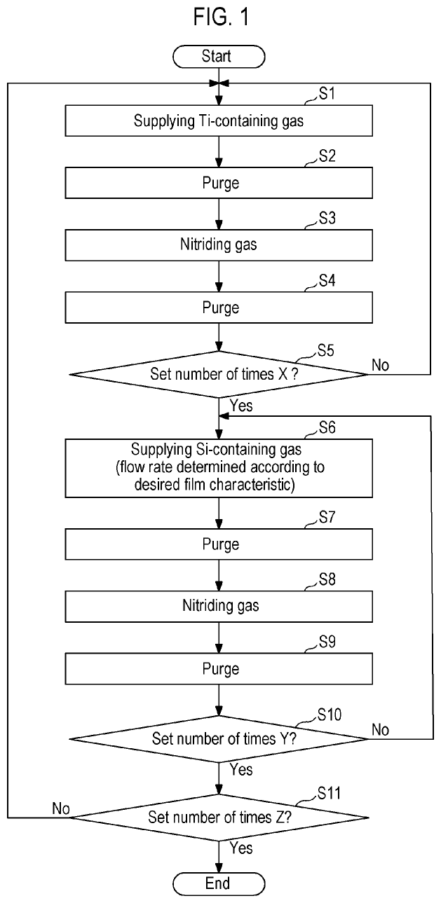

A film-forming method according to an embodiment of the present disclosure is a method of forming a titanium silicon nitride (TiSiN) film on a substrate by atomic layer deposition (ALD). Specifically, the film-forming method according to an embodiment of the present disclosure includes an operation of supplying a titanium (Ti)-containing gas and a nitrogen-containing gas in this order and an operation of supplying a silicon (Si)-containing gas and a nitrogen-containing gas in this order. Hereinafter, the operation of supplying the Ti-containing gas and the nitrogen-containing gas in this order will be referred to as the “TiN-forming cycle,” and the operation of supplying the Si-containing gas and the nitrogen-containing gas in this order will be referred to as the “SiN-forming cycle.” FIG. 1 is a flowchart illustrating a method of forming a TiSiN film according to an embodiment of the present disclosure.

First, a substrate is accommodated in a process container, an inside of the process container is maintained in a decompressed state, and a temperature of the substrate is adjusted to a predetermined temperature.

Next, a TiN-forming cycle is performed. First, a Ti-containing gas is supplied into the process container in which the substrate is accommodated (step S1). Thus, Ti is deposited on the substrate to form a Ti layer. A processing time of step S1 may be, for example, 0.3 seconds or less. As the Ti-containing gas, titanium tetrachloride (TiCl₄) gas, tetrakis-dimethylamino titanium (TDMAT) gas, tetrakis-ethylmethylamino titanium (TEMAT) gas, or the like may be used. In an embodiment, the Ti-containing gas is TiCl₄ gas, and the processing time is 0.05 seconds.

Subsequently, after exhausting the Ti-containing gas from the inside of the process container, the inside of the process container is purged by a purge gas (step S2). Nitrogen (N₂) gas, argon (Ar) gas, or the like may be used as the purge gas. In an embodiment of the present disclosure, the purge gas is N₂ gas, and the processing time is 0.2 seconds.

Subsequently, a nitrogen-containing gas is supplied into the process container (step S3). As a result, the Ti layer formed on the substrate is nitrided to form a TiN layer. As the nitrogen-containing gas, ammonia (NH₃) gas, hydrazine (N₂H₄) gas, monomethyl hydrazine (MMH) gas, or the like may be used. In an embodiment of the present disclosure, the nitrogen-containing gas is NH₃ gas, and the processing time is 0.3 seconds.

Subsequently, after exhausting the nitrogen-containing gas from the inside of the process container, the inside of the process container is purged by an inert gas (step S4). As the purge gas, a gas, which is the same as the purge gas used in step S2, may be used. In an embodiment, the purge gas is N₂ gas, and the processing time is 0.3 seconds.

Next, it is determined whether or not the number of times the TiN-forming cycle (step S1 to step S4) is executed has reached a predetermined number of times X (X is an integer of 1 or more) (step S5). In the step S5, when the number of times the TiN-forming cycle is executed has not reached the predetermined number of times X, the process returns to the step S1 and the TiN-forming cycle is executed again. As such, by repeating the TiN-forming cycle until the predetermined number of times X is reached, a TiN film having a predetermined film thickness is formed on the substrate. In the step S5, when the number of times the TiN-forming cycle is executed reaches the predetermined number of times X, the process proceeds to step S6.

Next, a SiN-forming cycle is performed. First, a Si-containing gas having a flow rate determined according to desired film characteristics is supplied into the process container (step S6). As a result, Si is deposited on the TiN film to form a Si layer. The flow rate determined according to the desired film characteristics is determined based on the desired film characteristics and relationship information indicating a relationship between predetermined film characteristics and the flow rate of the Si-containing gas. The relationship information may be, for example, a table or a mathematical expression. The desired film characteristics may include a resistivity (specific resistance) of the TiSiN film, a Si concentration in the TiSiN film, and the like. The processing time of step S6 may be the same as the processing time of step S1, may be different from the processing time of step S1, or may be, for example, 3.0 seconds or less. As the Si-containing gas, dichlorosilane (DCS), monosilane (SiH₄) or the like may be used. In an embodiment of the present disclosure, the Si-containing gas is DSC gas, and the processing time is 0.05 seconds.

Subsequently, after exhausting a Si source gas from the inside of the process container, the inside of the process container is purged by an inert gas (step S7). As the purge gas, a gas, which is the same as the purge gas used in step S2, may be used. In an embodiment, the purge gas is N₂ gas, and the processing time is 0.2 seconds.

Subsequently, a nitrogen-containing gas is supplied into the process container (step S8). As a result, the Si layer formed on the TiN film is nitrided to form a SiN layer. As the nitrogen-containing gas, a gas, which is the same as the nitrogen-containing gas used in step S3, may be used. In an embodiment of the present disclosure, the nitrogen-containing gas is NH₃ gas, and the processing time is 0.3 seconds.

Subsequently, after exhausting the nitrogen-containing gas from the inside of the process container, the inside of the process container is purged by a purge gas (step S9). As the purge gas, a gas, which is the same as the purge gas used in step S2, may be used. In an embodiment of the present disclosure, the purge gas is N₂ gas, and the processing time is 0.3 seconds.

Next, it is determined whether or not the number of times the SiN-forming cycle (step S6 to step S9) is executed has reached a predetermined number of times Y (Y is an integer of 1 or more) (step S10). In the step S10, when the number of times the SiN-forming cycle is executed has not reached the predetermined number of times Y, the process returns to step S6 and the SiN-forming cycle is executed again. As such, by repeating the SiN-forming cycle until the predetermined number of times Y is reached, a SiN film having a predetermined film thickness is formed on the TiN film. In the step S10, when the number of times the SiN-forming cycle is executed reaches the frequency Y, the process proceeds to step S11.

Next, it is determined whether or not the number of times the TiN-forming cycle executed X times and the SiN-forming cycle executed Y times (hereinafter, referred to as “TiSiN-forming cycle”) are executed reaches a predetermined number of times Z (Z is 1 or more) (step S11). In the step S11, when the number of times the TiSiN-forming cycle is executed has not reached the predetermined number of times Z, the process returns to step S1 and the TiSiN-forming cycle is executed again. As such, by repeating the TiSiN-forming cycle until the number of times Z is reached, a Si layer having a predetermined film thickness is doped, and a TiSiN film having desired film characteristics is formed on the substrate. In the step S11, when the number of times the TiSiN-forming cycle is executed reaches the number of times Z, the film formation of the TiSiN film is terminated.

When forming the TiSiN film through an ALD method, it is possible to adjust the film characteristics of the TiSiN film by changing a ratio of the number of times X of the TiN-forming cycle and the number of times Y of the SiN-forming cycle. For example, when a substrate temperature is 400 degrees C., by setting the ratio of the number of times X to the number of times Y to X:Y=1:1, 1:2, or 1:3, it is possible to adjust Si/(Si+Ti), which is the Si concentration in the TiSiN film, to 46%, 53%, and 59%, respectively. However, in the method of changing the ratio of the number of times X and the number of times Y, the Si concentration in the obtained film may be discretely adjusted, but may not be continuously adjusted.

Meanwhile, according to the film-forming method according to an embodiment of the present disclosure, in the step of supplying the Si-containing gas into the process container (step S6), the flow rate of the Si-containing gas is controlled to be a flow rate determined according to the desired film characteristics. Specifically, for example, the flow rate of the Si-containing gas is controlled to be a flow rate determined based on the desired film characteristics and relationship information indicating the relationship between the predetermined film characteristics and the flow rate of the Si-containing gas. Here, the flow rate of the Si-containing gas is a parameter, which is finely controllable, for example, every 1 sccm. Therefore, it is possible to continuously adjust the resistivity of the TiSiN film and the Si concentration in the film by finely controlling the flow rate of the Si-containing gas. In other words, it is possible to perform a control of film characteristics more finely. As a result, it is possible to form a TiSiN film having desired film characteristics.

In addition to the flow rate of the Si-containing gas described above, the number of times X, the number of times Y, and the number of times Z, the supply time of the Ti-containing gas, the supply time of the Si-containing gas, and the like may be controlled to obtain desired film characteristics. As a result, it is possible to expand an adjustment range of the film characteristic.

(Film-Forming Apparatus)

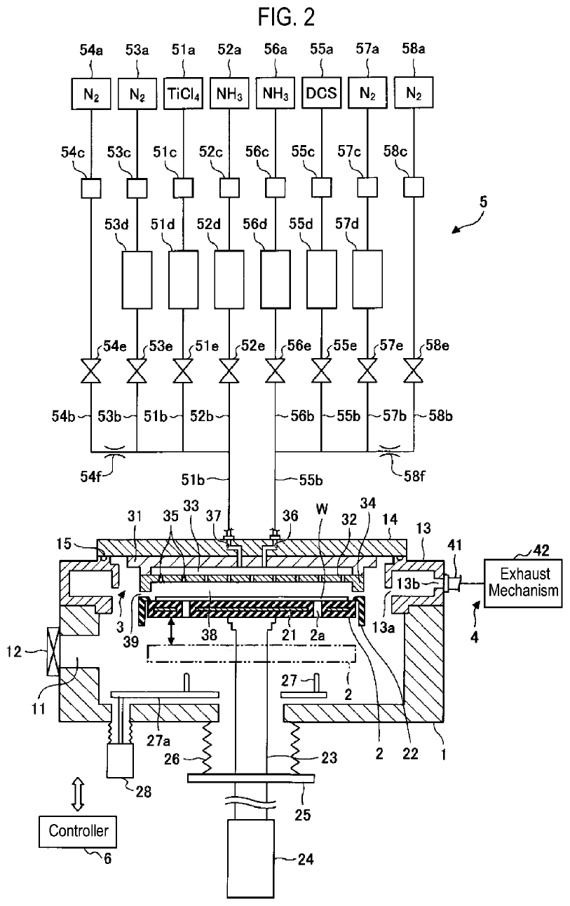

An example of a film-forming apparatus, which implements a method of forming the TiSiN film will be described. FIG. 2 is a schematic view illustrating an exemplary configuration of the film-forming apparatus.

The film-forming apparatus has a process container 1, a stage 2, a shower head 3, an exhaust part 4, a gas supply mechanism 5, and a controller 6.

The process container 1 is made of a metal such as aluminum, and has a substantially cylindrical shape. The process container 1 accommodates a semiconductor wafer (hereinafter referred to as a “wafer W”) which is an example of a substrate to be processed. A loading/unloading port 11 is formed in the side wall of the process container 1 to load/unload a wafer W therethrough, and is opened/closed by a gate valve 12. An annular exhaust duct 13 having a rectangular cross section is provided on the main body of the process container 1. A slit 13a is formed in the exhaust duct 13 along the inner peripheral surface. An exhaust port 13b is formed in the outer wall of the exhaust duct 13. On the upper surface of the exhaust duct 13, a ceiling wall 14 is provided so as to close the upper opening of the process container 1. A space between the exhaust duct 13 and the ceiling wall 14 is hermetically sealed with a seal ring 15.

The stage 2 horizontally supports the wafer W in the process container 1. The stage 2 is formed in a disk shape having a size corresponding to the wafer W. The stage 2 is formed of a ceramics material, such as aluminum nitride (AlN) or a metal material, such as aluminum or nickel alloy. A heater 21 is embedded in the stage 2 to heat the wafer W. The heater 21 is fed with power from a heater power supply (not illustrated) and generates heat. Then, the wafer W is controlled to a predetermined temperature by controlling the output of the heater 21 by a temperature signal of a thermocouple (not illustrated) provided in the vicinity of the upper surface of the stage 2. The stage 2 is provided with a cover member 22 formed of ceramics such as alumina so as to cover the outer peripheral area of the upper surface and the side surface thereof.

A support member 23 is provided under the stage 2 to support the stage 2. The support member 23 extends to the lower side of the process container 1 through a hole formed in the bottom wall of the process container 1 from the center of the bottom surface of the stage 2, and the lower end of the support member 123 is connected to a lifting mechanism 24. The substrate stage 2 ascends/descends via the support member 23 by the lifting mechanism 24 between a processing position illustrated in FIG. 1 and a transport position indicated by a two-dot chain line below the processing position where the wafer W is capable of being transported. Below the process container 1, a flange part 25 is mounted on the support member 23. A bellows 26, which partitions the atmosphere in the process container 1 from the outside air, is provided between the bottom surface of the process container 1 and the flange part 25 to expand and contract in response to the ascending/descending movement of the stage 2.

Three wafer support pins 27 (only two are illustrated) are provided in the vicinity of the bottom surface of the process container 1 to protrude upward from a lifting plate 27a. The wafer support pins 27 ascend/descend via the lifting plate 27a by a lifting mechanism 28 provided below the process container 1. The wafer support pins 27 are inserted through the through holes 2a provided in the stage 2 located at the transport position and are configured to protrude/retract with respect to the upper surface of the stage 2. By causing the wafer support pins 27 to ascend/descend, the wafer W is delivered between a wafer transport mechanism (not illustrated) and the stage 2.

The shower head 3 supplies a processing gas into the process container 1 in a shower form. The shower head 3 is made of a metal and is provided to face the substrate stage 2. The shower head 3 has a diameter, which is substantially equal to that of the substrate stage 2. The shower head 3 has a main body 31 fixed to the ceiling wall 14 of the process container 1 and a shower plate 32 connected to the lower side of the main body 31. A gas diffusion space 33 is formed between the main body 31 and the shower plate 32. In the gas diffusion space 33, gas introduction holes 36 and 37 are provided through the center of the main body 31 and the ceiling wall 14 of the process container 1. An annular protrusion 34 protruding downward is formed on the peripheral edge portion of the shower plate 32. Gas ejection holes 35 are formed in the flat surface inside the annular protrusion 34. In the state in which the stage 2 is in the processing position, a processing space 38 is formed between the stage 2 and the shower plate 32, and the upper surface of the cover member 22 and the annular protrusion 34 are close to each other so as to form an annular gap 39.

The exhaust part 4 evacuates the inside of the process container 1. The exhaust part 4 includes an exhaust pipe 41 connected to the exhaust port 13b, and an exhaust mechanism 42 connected to the exhaust pipe 41 and having, for example, a vacuum pump and a pressure control valve. During the processing, the gas in the process container 1 reaches the exhaust duct 13 via the slit 13a, and is exhausted from the exhaust duct 13 through the exhaust pipe 41 by the exhaust mechanism 42.

The gas supply mechanism 5 supplies a processing gas into the process container 1. The gas supply mechanism 5 includes a Ti-containing gas supply source 51a, a nitrogen-containing gas supply source 52a, an N₂ gas supply source 53a, an N₂ gas supply source 54a, a Si-containing gas supply source 55a, a nitrogen-containing gas supply source 56a, an N₂ gas supply source 57a, and an N₂ gas supply source 58a.

The Ti-containing gas supply source 51a supplies TiCl₄ gas, which is an example of a Ti-containing gas, into the process container 1 through a gas supply line 51b. The gas supply line 51b is provided with a flow rate controller 51c, a storage tank 51d, and a valve 51e from the upstream side. The downstream side of the valve 51e of the gas supply line 51b is connected to the gas introduction hole 37. TiCl₄ gas supplied from the Ti-containing gas supply source 51a is temporarily stored in the storage tank 51d before being supplied into the process container 1, is pressurized to a predetermined pressure in the storage tank 51d, and is then supplied into the process container 1. Supply and stop of the TiCl₄ gas from the storage tank 51d to the process container 1 are performed by the valve 51e. By temporarily storing the TiCl₄ gas in the storage tank 51d as described above, it is possible to stably supply the TiCl₄ gas into the process container 1 at a relatively large flow rate.

The nitrogen-containing gas supply source 52a supplies NH₃ gas, which is an example of a nitrogen-containing gas, into the process container 1 through the gas supply line 52b. The gas supply line 52b is provided with a flow rate controller 52c, a storage tank 52d, and a valve 52e from the upstream side. The downstream side of the valve 52e of the gas supply line 52b is connected to the gas supply line 51b. The NH₃ gas supplied from the nitrogen-containing gas supply source 52a is temporarily stored in the storage tank 52d before being supplied into the process container 1, is pressurized to a predetermined pressure in the storage tank 52d, and is then supplied into the process container 1. Supply and stop of the NH₃ gas from the storage tank 52d to the process container 1 are performed by the valve 52e. By temporarily storing the NH₃ gas in the storage tank 52d as described above, it is possible to stably supply the NH₃ gas into the process container 1 at a relatively large flow rate.

The N₂ gas supply source 53a supplies N₂ gas, which is an example of a purge gas, into the process container 1 through the gas supply line 53b. The gas supply line 53b is provided with a flow rate controller 53c, a storage tank 53d, and a valve 53e from the upstream side. The downstream side of the valve 53e of the gas supply line 53b is connected to the gas supply line 51b. The N₂ gas supplied from the N₂ gas supply source 53a is temporarily stored in the storage tank 53d before being supplied into the process container 1, is pressurized to a predetermined pressure in the storage tank 53d, and is then supplied into the process container 1. Supply and stop of the N₂ gas from the storage tank 53d to the process container 1 are performed by the valve 53e. By temporarily storing the N₂ gas in the storage tank 53d as described above, it is possible to stably supply the N₂ gas into the process container 1 at a relatively large flow rate.

The N₂ gas supply source 54a supplies N₂ gas, which is an example of a carrier gas, into the process container 1 through the gas supply line 54b. The gas supply line 54b is provided with a flow rate controller 54c, a valve 54e, and an orifice 54f from the upstream side. The downstream side of the orifice 54f of the gas supply line 54b is connected to the gas supply line 51b. The N₂ gas supplied from the N₂ gas supply source 54a is continuously supplied into the process container 1 during the film formation on the wafer W. Supply and stop of the N₂ gas from the N₂ gas supply source 54a to the process container 1 are performed by the valve 54e. The orifice 54f hinders a relatively large flow rate of gas, supplied to the gas supply lines 51b, 52b, and 53b from the storage tanks 51d, 52d, and 53d, from flowing backward to the N₂ gas supply line 54b.

The Si-containing gas supply source 55a supplies DCS gas, which is an example of a Si-containing gas, into the process container 1 through the gas supply line 55b. The gas supply line 55b is provided with a flow rate controller 55c, a storage tank 55d, and a valve 55e from the upstream side. The downstream side of the valve 55e of the gas supply line 55b is connected to the gas introduction hole 36. The DCS gas supplied from the Si-containing gas supply source 55a is temporarily stored in the storage tank 55d before being supplied into the process container 1, is pressurized to a predetermined pressure in the storage tank 55d, and is then supplied into the process container 1. Supply and stop of the DCS gas from the storage tank 55d to the process container 1 are performed by the valve 55e. By temporarily storing the DCS gas in the storage tank 55d as described above, it is possible to stably supply the DCS gas into the process container 1 at a relatively large flow rate.

The nitrogen-containing gas supply source 56a supplies NH₃ gas, which is an example of a nitrogen-containing gas, into the process container 1 through the gas supply line 56b. The gas supply line 56b is provided with a flow rate controller 56c, a storage tank 56d, and a valve 56e from the upstream side. The downstream side of the valve 56e of the gas supply line 56b is connected to the gas supply line 55b. The NH₃ gas supplied from the nitrogen-containing gas supply source 56a is temporarily stored in the storage tank 56d before being supplied into the process container 1, is pressurized to a predetermined pressure in the storage tank 56d, and is then supplied into the process container 1. Supply and stop of the NH₃ gas from the storage tank 56d to the process container 1 are performed by the valve 56e. By temporarily storing the NH₃ gas in the storage tank 56d as described above, it is possible to stably supply the NH₃ gas into the process container 1 at a relatively large flow rate.

The N₂ gas supply source 57a supplies N₂ gas, which is an example of a purge gas, into the process container 1 through the gas supply line 57b. The gas supply line 57b is provided with a flow rate controller 57c, a storage tank 57d, and a valve 57e from the upstream side. The downstream side of the valve 57e of the gas supply line 57b is connected to the gas supply line 55b. The N₂ gas supplied from the N₂ gas supply source 57a is temporarily stored in the storage tank 57d before being supplied into the process container 1, is pressurized to a predetermined pressure in the storage tank 57d, and is then supplied into the process container 1. Supply and stop of the N₂ gas from the storage tank 57d to the process container 1 are performed by the valve 57e. By temporarily storing the N₂ gas in the storage tank 57d as described above, it is possible to stably supply the N₂ gas into the process container 1 at a relatively large flow rate.

The N₂ gas supply source 58a supplies N₂ gas, which is an example of a carrier gas, into the process container 1 through the gas supply line 58b. The gas supply line 58b is provided with a flow rate controller 58c, a valve 58e, and an orifice 58f from the upstream side. The downstream side of the orifice 58f of the gas supply line 58b is connected to the gas supply line 55b. The N₂ gas supplied from the N₂ gas supply source 58a is continuously supplied into the process container 1 during the film formation on the wafer W. Supply and stop of the N₂ gas from the N₂ gas supply source 58a to the process container 1 are performed by the valve 58e. The orifice 58f hinders a gas having a relatively large flow rate that is supplied from the storage tanks 55d, 56d, and 57d to the gas supply lines 55b, 56b, and 57b from flowing backward to the N₂ gas supply line 58b.

The controller 6 is, for example, a computer, and includes, for example, a central processing unit (CPU), a random access memory (RAM), a read only memory (ROM), and an auxiliary storage device. The CPU operates on the basis of a program stored in the ROM or the auxiliary storage device, and controls operations of the film-forming apparatus. The controller 6 may be provided either inside or outside the film-forming apparatus. In the case where the controller 6 is provided outside the film-forming apparatus 1, the controller 6 is capable of controlling the film-forming apparatus through a wired or wireless communication mechanism.

Next, an example of a method of forming a TiSiN film on a wafer W using the film-forming apparatus of FIG. 2 will be described with reference to FIGS. 1 and 2.

First, in the state in which the valves 51e to 58e are closed, the gate valve 12 is opened, the wafer W is transported into the process container 1 by the transport mechanism (not illustrated), and the wafer W is placed on the stage 2 at the transport position. After making the transport mechanism retreat from the inside of the process container 1, the gate valve 12 is closed. The wafer W is heated to a predetermined temperature (e.g., 350 degrees C. to 450 degrees C.) by the heater 21 of the stage 2, and the stage 2 is raised to the processing position to form the processing space 38. In addition, the pressure control valve of the exhaust mechanism 42 adjusts the inside of the process container 1 to a predetermined pressure (e.g., 200 Pa to 1000 Pa).

Next, the valves 54e and 58e are opened, and a carrier gas (N₂ gas) of a predetermined flow rate (e.g., 300 to 10000 sccm) is supplied from the N₂ gas supply sources 54a and 58a to the gas supply lines 54b and 58b, respectively. In addition, TiCl₄ gas, NH₃ gas, DCS gas, and NH₃ gas are supplied from the Ti-containing gas supply source 51a, the nitrogen-containing gas supply source 52a, the Si-containing gas supply source 55a, and the nitrogen-containing gas supply source 56a to the gas supply lines 51b, 52b, 55b, and 56b, respectively. At this time, since the valves 51e, 52e, 55e, and 56e are closed, the TiCl₄ gas, the NH₃ gas, the DCS gas, and the NH₃ gas are stored in the storage tanks 51d, 52d, 55d, and 56d, respectively, and the inside of the storage tanks 51d, 52d, 55d, and 56d are pressurized.

Next, the valve 51e is opened and the TiCl₄ gas stored in the storage tank 51d is supplied into the process container 1 so as to be adsorbed onto the surface of the wafer W (step S1). Further, in parallel with the supply of the TiCl₄ gas into the process container 1, the purge gas (N₂ gas) is supplied from the N₂ gas supply sources 53a and 57a to the gas supply lines 53b and 57b, respectively. At this time, since the valves 53e and 57e are closed, the purge gas is stored in the storage tanks 53d and 57d, and the inside of the storage tanks 53d and 57d is pressurized.

After a predetermined time (e.g., 0.03 to 0.3 seconds) elapses after the valve 51e is opened, the valve 51e is closed and the valves 53e and 57e are opened. Therefore, supply of the TiCl₄ gas into the process container 1 is stopped, and the purge gas stored in each of the storage tanks 53d and 57d is supplied into the process container 1 (step S2). At this time, since the purge gas is supplied from the storage tanks 53d and 57d in the state of being pressurized, the purge gas is supplied into the process container 1 at a relatively large flow rate (e.g., a flow rate larger than the flow rate of the carrier gas). Therefore, the TiCl₄ gas remaining in the process container 1 is quickly exhausted to the exhaust pipe 41, and the inside of the process container 1 is replaced from the TiCl₄ gas atmosphere to the N₂ gas atmosphere in a short time. Meanwhile, by closing the valve 51e, the TiCl₄ gas supplied from the Ti-containing gas supply source 51a to the gas supply line 51b is stored in the storage tank 51d, and the inside of the storage tank 51d is pressurized.

After a predetermined time (e.g., 0.1 to 0.3 seconds) elapses after the valves 53e and 57e are opened, the valves 53e and 57e are closed and the valve 52e is opened. Therefore, supply of the purge gas into the process container 1 is stopped, the NH₃ gas stored in the storage tank 52d is supplied into the process container 1 so as to nitride the TiCl₄ gas adsorbed onto the wafer W (step S3) At this time, by closing the valves 53e and 57e, the purge gas respectively supplied from the N₂ gas supply sources 53a and 57a to the gas supply lines 53b and 57b is stored in the storage tanks 53d and 57d, and the inside of the storage tanks 53d and 57d is pressurized.

After a predetermined time (e.g., 0.2 to 3.0 seconds) elapses after the valve 52e is opened, the valve 52e is closed and the valves 53e and 57e are opened. Therefore, supply of the NH₃ gas into the process container 1 is stopped, and the purge gas stored in each of the storage tanks 53d and 57d is supplied into the process container 1 (step S4). At this time, since the purge gas is supplied from the storage tanks 53d and 57d in the state of being pressurized, the purge gas is supplied into the process container 1 at a relatively large flow rate (e.g., a flow rate larger than the flow rate of the carrier gas). Therefore, the NH₃ gas remaining in the process container 1 is quickly exhausted to the exhaust pipe 41, and the inside of the process container 1 is replaced from the NH₃ gas atmosphere to the N₂ gas atmosphere in a short time. Meanwhile, by closing the valve 52e, the NH₃ gas supplied from the nitrogen-containing gas supply source 52a to the gas supply line 52b is stored in the storage tank 52d, and the inside of the storage tank 52d is pressurized.

A thin TiN unit film is formed on the wafer W by performing one cycle of steps S1 to S4 described above. Then, the cycle of steps S1 to S4 is repeated by a predetermined number of times X (step S5).

Next, the valve 55e is opened, and the DCS gas stored in the storage tank 55d is supplied into the process container 1 so as to be adsorbed onto the TiN film (step S6). At this time, the flow rate controller 55c provided in the gas supply line 55b is controlled so as to provide the DCS gas, the flow rate of which is determined according to desired film characteristics. In addition, in parallel with the supply of the DCS gas into the process container 1, the purge gas (N₂ gas) is supplied from the N₂ gas supply sources 53a and 57a to the gas supply lines 53b and 57b, respectively. At this time, since the valves 53e and 57e are closed, the purge gas is stored in the storage tanks 53d and 57d, and the inside of the storage tanks 53d and 57d is pressurized.

After a predetermined time (e.g., 0.05 to 3.0 seconds) elapses after the valve 55e is opened, the valve 55e is closed and the valves 53e and 57e are opened. Therefore, supply of the DCS gas into the process container 1 is stopped, and the purge gas stored in each of the storage tanks 53d and 57 is supplied into the process container 1 (step S7). At this time, since the purge gas is supplied from the storage tanks 53d and 57d in the state of being pressurized, the purge gas is supplied into the process container 1 at a relatively large flow rate (e.g., a flow rate larger than the flow rate of the carrier gas). Therefore, the DCS gas remaining in the process container 1 is quickly exhausted to the exhaust pipe 41, and the inside of the process container 1 is replaced from the DCS gas atmosphere to the N₂ gas atmosphere in a short time. Meanwhile, by closing the valve 55e, the DCS gas supplied from the Si-containing gas supply source 55a to the gas supply line 55b is stored in the storage tank 55d, and the inside of the storage tank 55d is pressurized.

After a predetermined time (e.g., 0.1 to 0.3 seconds) elapses after the valves 53e and 57e are opened, the valves 53e and 57e are closed and the valve 56e is opened. Therefore, supply of the purge gas into the process container 1 is stopped, the NH₃ gas stored in the storage tank 56d is supplied into the process container 1 so as to nitride the DCS gas adsorbed onto the wafer W (step S8) At this time, by closing the valves 53e and 57e, the purge gas respectively supplied from the N₂ gas supply sources 53a and 57a to the gas supply lines 53b and 57b is stored in the storage tanks 53d and 57d, and the inside of the storage tanks 53d and 57d is pressurized.

After a predetermined time (e.g., 0.2 to 3.0 seconds) elapses after the valve 56e is opened, the valve 56e is closed and the valves 53e and 57e are opened. Therefore, supply of the NH₃ gas into the process container 1 is stopped, and the purge gas stored in each of the storage tanks 53d and 57d is supplied into the process container 1 (step S9). At this time, since the purge gas is supplied from the storage tanks 53d and 57d in the state of being pressurized, the purge gas is supplied into the process container 1 at a relatively large flow rate (e.g., a flow rate larger than the flow rate of the carrier gas). Therefore, the NH₃ gas remaining in the process container 1 is quickly exhausted to the exhaust pipe 41, and the inside of the process container 1 is replaced from the NH₃ gas atmosphere to the N₂ gas atmosphere in a short time. Meanwhile, by closing the valve 56e, the NH₃ gas supplied from the nitrogen-containing gas supply source 56a to the gas supply line 56b is stored in the storage tank 56d, and the inside of the storage tank 56d is pressurized.

A thin SiN unit film is formed on the TiN film by performing one cycle of steps S6 to S9 described above. Then, the cycle of steps S6 to S9 is repeated by a predetermined number of times Y (step S10).

Next, the cycle of steps S1 to S4 and steps S6 to S9 is repeated by a predetermined number of times Z (step S11). By repeating the cycle of steps S1 to S4 and steps S6 to S9 until the number of times Z is reached, a Si layer having a predetermined film thickness is doped, and a TiSiN film having desired film characteristics is formed on the wafer.

Thereafter, the wafer W is unloaded from the process container 1 in the reverse procedure to that at the time of loading the wafer W into the process container 1.

In the above-described example, the case in which the purge gas (N₂ gas) stored in the storage tanks 53d and 57d is supplied into the process container 1 to purge the inside of the process container 1 in the steps S2, S4, S7, and S9 have been described, the present disclosure is not limited thereto. For example, the inside of the process container 1 may be purged by the carrier gas (N₂ gas) supplied from the N₂ gas supply sources 54a and 58a into the process container 1 without supplying the purge gas (N₂ gas) stored in the storage tanks 53d and 57d into the process container 1.

(Evaluation)

Next, by the film-forming method according to the exemplary embodiment described with reference to FIG. 1, a ratio of the number of times X to the number of times Y, the number of times Z, and a flow rate of DCS, which is an example of the Si-containing gas, are changed to form TiSiN films, and a resistivity and a Si concentration in film of each of the TiSiN films are measured. Process conditions are as follows.

<Process Condition>

Substrate temperature: 400 degrees C.

Ratio of number of times X and number of times Y (X:Y): 1:2, 1:1

Number of times Z: 67 times, 75 times

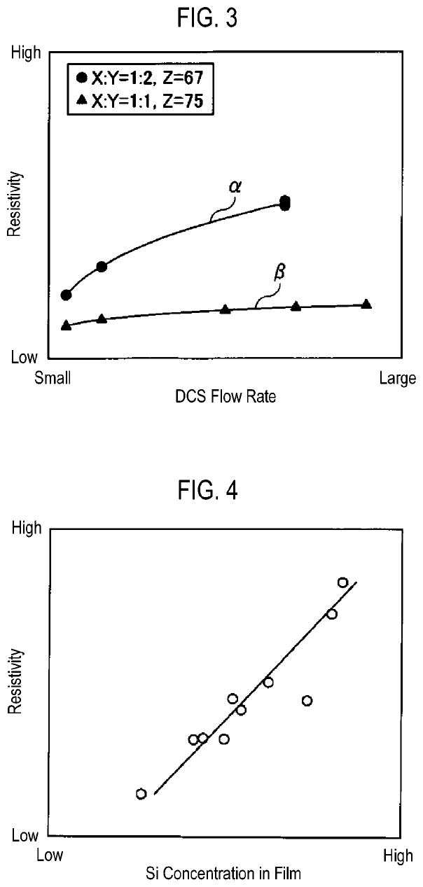

FIG. 3 is a diagram representing an exemplary relationship between a DCS flow rate and resistivity. In FIG. 3, the horizontal axis represents a DCS flow rate, and the vertical axis represents resistivity. In addition, in FIG. 3, “●” indicates a result in the case in which X:Y=1:2, and “▴” indicates a result in the case in which X:Y=1:1.

First, the case in which X:Y=1:2 and Z=67 is considered. As indicated by “●” in FIG. 3, it can be seen that the resistivity of the TiSiN film decreases as the DCS flow rate decreases. Here, the DSC flow rate is a parameter, which is finely controllable, for example, every 1 sccm. Therefore, it can be said that it is possible to continuously adjust the resistivity of the TiSiN film as represented by a curve α in FIG. 3 by finely controlling the DCS flow rate, for example, every 1 sccm.

Next, the case in which X:Y=1:1 and Z=75 is considered. As indicated by “▴” in FIG. 3, it can be seen that the resistivity of the TiSiN film decreases as the DCS flow rate decreases. Here, the DSC flow rate is a parameter, which is finely controllable, for example, every 1 sccm. Therefore, it can be said that it is possible to continuously adjust the resistivity of the TiSiN film as represented by a curve β in FIG. 3 by finely controlling the DCS flow rate, for example, every 1 sccm.

In addition, as illustrated in FIG. 3, it can be seen that an amount of change in resistivity of the TiSiN film when the DCS flow rate is changed is smaller in the case where X:Y is set to 1:1 and Z is set to 75 (“▴” in FIG. 3) than in the case where X:Y is set to 1:2 and Z is set to 67 (“●” in FIG. 3). From this point, it can be said that it is possible to finely adjust the resistivity of the TiSiN film when setting X:Y to 1:1 and setting Z to 75, as compared with when setting X:Y to 1:2 and setting Z to 67.

FIG. 4 is a diagram representing an exemplary relationship between a Si concentration in a film and resistivity. In FIG. 4, the horizontal axis represents a Si concentration, and the vertical axis represents resistivity.

As represented in FIG. 4, it can be seen that the Si concentration in the film and the resistivity are approximately proportional to each other. From this, it can be said that it is possible to continuously adjust the Si concentration in the film by finely controlling the DCS flow rate and continuously adjusting the resistivity.

According to the present disclosure, it is possible to form a TiSiN film having desired film characteristics.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of forming a TiSiN film having a desired film characteristic, the method comprising:
forming a TiN film by executing an operation of supplying, into a process container in which a substrate is accommodated, a Ti-containing gas and a nitrogen-containing gas in this order a number of times X, X being an integer of 1 or more; and
forming a SiN film by executing an operation of supplying, into the process container, a Si-containing gas and the nitrogen-containing gas in this order a number of times Y, Y being an integer of 1 or more,
wherein forming a TiN film and forming a SiN film are executed in this order a number of times Z, Z being an integer of 1 or more, and
wherein, in forming a SiN film, a flow rate of the Si-containing gas is controlled to be a flow rate determined according to the desired film characteristic.

2. The method of claim 1, wherein the flow rate determined according to the desired film characteristic is determined based on the desired film characteristic and relationship information indicating a relationship between a predetermined film characteristic and the flow rate of the Si-containing gas.

3. The method of claim 1, wherein forming a SiN film includes supplying the Si-containing gas, which is pressurized to a predetermined pressure by being stored in a storage tank, into the process container, and
wherein the flow rate of the Si-containing gas is a flow rate when the Si-containing gas is stored in the storage tank.

4. The method of claim 1, wherein a processing time required when forming a TiN film is executed one time is 0.1 seconds or less.

5. The method of claim 1, wherein a processing time required when forming a SiN film is executed one time is 0.1 seconds or less.

6. The method of claim 1, wherein the desired film characteristic is resistivity.

7. The method of claim 1, wherein the desired film characteristic is a Si concentration in film.

8. A film-forming apparatus comprising:
a process container configured to accommodate a substrate therein;
a gas supply mechanism configured to supply a Ti-containing gas, a Si-containing gas, and a nitrogen-containing gas into the process container; and
a controller,
wherein the controller is configured to control the gas supply mechanism to execute a process including:
forming a TiN film by executing an operation of supplying, into the process container, the Ti-containing gas and the nitrogen-containing gas in this order a number of times X, X being an integer of 1 or more; and
forming a SiN film by executing an operation of supplying, into the process container, the Si-containing gas and the nitrogen-containing gas in this order a number of times Y, Y being an integer of 1 or more,
wherein forming a TiN film and forming a SiN film are executed in this order a number of times Z, Z being an integer of 1 or more; and
wherein, in forming a SiN film, a flow rate of the Si-containing gas is controlled to be a flow rate determined according to a desired film characteristic.
